(19) United States
(12) Patent Application Publication
(10) Pub. No.: US 2015/0048458 A1
(43) Pub. Date: Feb. 19, 2015

(54) SEMICONDUCTOR DEVICE AND MANUFACTURING METHOD THEREOF

(71) Applicant: Institute of Microelectronics, Chinese Academy of Sciences, Beijing (CN)

(72) Inventors: Huilong Zhu, Poughkeepsie, NY (US); Qiuxia Xu, Beijing (CN); Yanbo Zhang, Beijing (CN); Hong Yang, Beijing (CN)

(21) Appl. No.: 14/387,305

(22) PCT Filed: Dec. 7, 2012
(86) PCT No.: PCT/CN2012/086129

§ 371 Date: Sep. 23, 2014

(30) Foreign Application Priority Data
Nov. 30, 2012 (CN) 201210506055.0

(51) Int. Cl. H01L 27/092; H01L 21/8238; H01L 21/265; H01L 21/324

(52) U.S. Cl. CPC H01L 27/0922; H01L 21/324; H01L 21/823842; H01L 21/265
USPC 257/369; 438/229

(57) ABSTRACT

Provided are a semiconductor device and a method for manufacturing the same. The method may include: forming source/drain regions in a semiconductor substrate; forming an interfacial oxide layer on the semiconductor substrate; forming a high K gate dielectric layer on the interfacial oxide layer; forming a first metal gate layer on the high K gate dielectric layer; implanting dopant to the first metal gate layer through conformal doping; and performing annealing to change an effective work function of a gate stack comprising the first metal gate layer, the high K gate dielectric layer, and the interfacial oxide layer.

### CROSS-REFERENCE TO RELATED APPLICATION

This application claims priority to Chinese Application No. 201210506055.0, entitled “SEMICONDUCTOR DEVICE AND METHOD FOR MANUFACTURING THE SAME,” filed on Nov. 30, 2012, which is incorporated herein by reference in its entirety.

### TECHNICAL FIELD

The present disclosure relates to the semiconductor technology, and particularly to semiconductor devices including metal gate and high K gate dielectric and methods for manufacturing the same.

### BACKGROUND

As the development of the semiconductor technology, Metal Oxide Semiconductor Field Effect Transistors (MOSFETs) have their feature sizes being decreased continuously. The decrease in size of the MOSFETs causes a severe problem of gate current leakage. The gate leakage current can be reduced by using a high K gate dielectric layer, which may have an increased physical thickness with respect to a given equivalent oxide thickness (EOT). Unfortunately, a conventional Poly-Si gate is incompatible with the high K gate dielectric layer. By using a combination of a metal gate and the high K gate dielectric layer, it is possible not only to avoid the depletion effect of the Poly-Si gate and decrease gate resistance, but also to avoid boron penetration and enhance device reliability. Therefore, the combination of the metal gate and the high K gate dielectric layer is widely used in the MOSFETs. However, integration of the metal gate and the high K gate dielectric layer is still confronted with many challenges, such as thermal stability and interfacial states. Particularly, due to the Fermi-Pinning Effect, it is difficult for the MOSEFTs using the metal gate and the high K gate dielectric layer to have an adequately low threshold voltage.

In CMOS applications with N type and P type MOSFETs integrated, the N type MOSFET should have an effective work function near the bottom of the conduction band of Si (about 4.1 eV), and the P type MOSFET should have an effective work function near the top of the valence band of Si (about 5.2 eV), in order to attain an appropriate threshold voltage. Different combinations of metal gate and high K gate dielectric may be selected for the N type and P type MOSFETs, respectively, to attain the desired threshold voltage. As a result, it is necessary to form dual metal gates and dual high K gate dielectrics on a single chip. Respective photolithography and etching processes need to be performed for the metal gates and high K gate dielectrics of the N type and P type MOSFETs during manufacture. Therefore, the processes for manufacturing such semiconductor devices including dual metal gates and dual high K gate dielectric layers are complicated, and not suitable for mass production, thereby incurring high cost.

### SUMMARY

The present disclosure intends to provide, among others, an improved semiconductor device and a method for manufacturing the same, by which it is possible to adjust an effective work function of the semiconductor device during manufacture thereof.

According to an aspect of the present disclosure, a method for manufacturing a semiconductor device is provided, comprising: forming source/drain regions in a semiconductor substrate; forming an interfacial oxide layer on the semiconductor substrate; forming a high K gate dielectric layer on the interfacial oxide layer; forming a first metal gate layer on the high K gate dielectric layer; implanting dopants to the first metal gate layer through conformal doping; and performing annealing to change an effective work function of a gate stack comprising the first metal gate layer, the high K gate dielectric layer, and the interfacial oxide layer. In a preferred embodiment, the semiconductor device may comprise N type and P type MOSFETs formed on a single semiconductor substrate. Dopant for decreasing the effective work function is implanted to the first metal gate layer of the N type MOSFET, and dopant for increasing the effective work function is implanted to the first metal gate layer of the P type MOSFET.

According to another aspect of the present disclosure, a semiconductor device is provided, comprising: source/drain regions in a semiconductor substrate; an interfacial oxide layer on the semiconductor substrate; a high K gate dielectric layer on the interfacial oxide layer; and a first metal gate layer on the high K gate dielectric layer, wherein dopants are distributed at an upper interface between the high K gate dielectric layer and the first metal gate layer as well as at a lower interface between the high K gate dielectric layer and the interfacial oxide layer, and generate electrical dipoles at the lower interface through an interfacial reaction, to change an effective work function of a gate stack comprising the first metal gate layer, the high K gate dielectric layer, and the interfacial oxide layer.

In accordance with the present disclosure, the dopants accumulated at the upper interface of the high K gate dielectric layer can change characteristics of the metal gate, thereby adjusting the effective work function of the corresponding MOSFET advantageously. On the other hand, the dopants accumulated at the lower interface of the high K gate dielectric layer can generate the electrical dipoles of proper polarity through the interfacial reaction, thereby further adjusting the effective work function of the corresponding MOSFET advantageously. The semiconductor device obtained by the method presents excellent stability and ability to adjustment of the effective work function of the metal gate. The effective work function can be decreased or increased by selecting different dopants for two types of MOSFETs. In CMOS devices, threshold voltages of two types of MOSFETs can be adjusted individually by simply changing the dopant, without using different combinations of metal gate and gate dielectric. Therefore, the method can omit respective deposition steps and masking and etching steps, simplifying the process and facilitating mass production. The conformal doping improves uniformity in distribution of the dopants, and thus suppresses random fluctuations of the threshold voltage.

In a preferred embodiment, the semiconductor device may further comprise a doped punch-through stop layer between the semiconductor substrate and the semiconductor fin, or a well in the semiconductor substrate. The doped punch-through stop layer and/or the well may have a doping type opposite to that of source/drain regions to reduce a leakage current between the source/drain regions.

### BRIEF DESCRIPTION OF THE DRAWINGS

For better understanding, the present disclosure will be described in detail with reference to the drawings, in which:

FIGS. 1 to 12 schematically shows sectional views of respective semiconductor structures during respective stages of a method for manufacturing a semiconductor device according to an embodiment of the present disclosure.

### DETAILED DESCRIPTION

The present invention will be described in more details below with reference to the accompanying drawings. In the following description, like components are indicated with like or similar reference signs. The drawings are not drawn to scale, for the sake of clarity.

In the following description, some specific details are set forth, such as structures, materials, sizes, and treatment processes and technologies of devices, in order to provide a thorough understanding of the present disclosure. However, it will be understood by those of ordinary skill in the art that the present disclosure may be practiced without these specific details. Each portion of a semiconductor device may comprise materials well known to those of ordinary skill in the art, or materials having similar functions to be developed in future, unless noted otherwise.

In the present disclosure, the term “semiconductor structure” refers to a semiconductor substrate and all layers or regions formed on the semiconductor substrate obtained after some operations during a process of manufacturing a semiconductor device. The term “source/drain region” refers to either a source region or a drain region of a MOSFET, and both of the source region and the drain region are labeled with a single reference sign. The term “N type dopant” refers to a dopant applicable to an N type MOSFET to reduce its effective work function, and the term “P type dopant” refers to a dopant applicable to a P type MOSFET to increase its effective work function.

A method for manufacturing a semiconductor device according to an embodiment of the present disclosure will be illustrated with reference to FIGS. 1 to 12, which show sectional views of respective semiconductor structures at various stages of the method. The semiconductor device is a CMOS device including N type and P type MOSFETs formed on a single semiconductor substrate.

FIG. 1 shows a semiconductor structure, which has gone through part of CMOS processes. Specifically, a P well 102a for an N type MOSFET and an N well 102b for a P type MOSFET are formed to a depth in a semiconductor substrate 101 (e.g., a Si substrate). In FIG. 1, the P well 102a and the N well 102b are shown in a rectangular shape and adjacent to each other. In practice, the P well 102a and the N well 102b may not have a clear boundary, and may be spaced by a portion of the semiconductor substrate 101. A shallow trench isolation 103 isolates active regions of the N-type MOSFET and the P-type MOSFET.

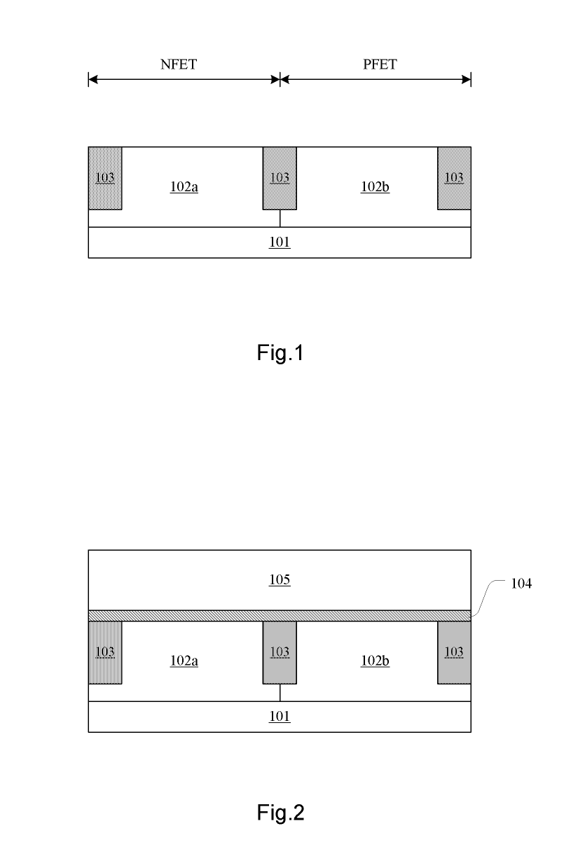

Then, a dummy gate dielectric layer 104 (e.g., silicon oxide, or silicon nitride) may be formed on the surface of the semiconductor structure through known deposition processes, such as Electron Beam evaporation (EBM), Chemical Vapor Deposition (CVD), Atomic Layer Deposition (ALD), or sputtering. In an example, the dummy gate dielectric layer 104 is a layer of silicon oxide having a thickness of about 0.8-1.5 nm. A dummy gate conductor 105 (e.g., poly-silicon, or amorphous silicon (α-Si)) is further formed on a surface of the dummy gate dielectric layer 104 through any of the above deposition processes, as shown in FIG. 2.

Thereafter, a photoresist layer PR1 is formed on the dummy gate dielectric layer 104 through, for example, spin coating. The photoresist layer PR1 is patterned to define a shape (e.g., strip) of a gate stack through a photolithographic process including exposure and development.

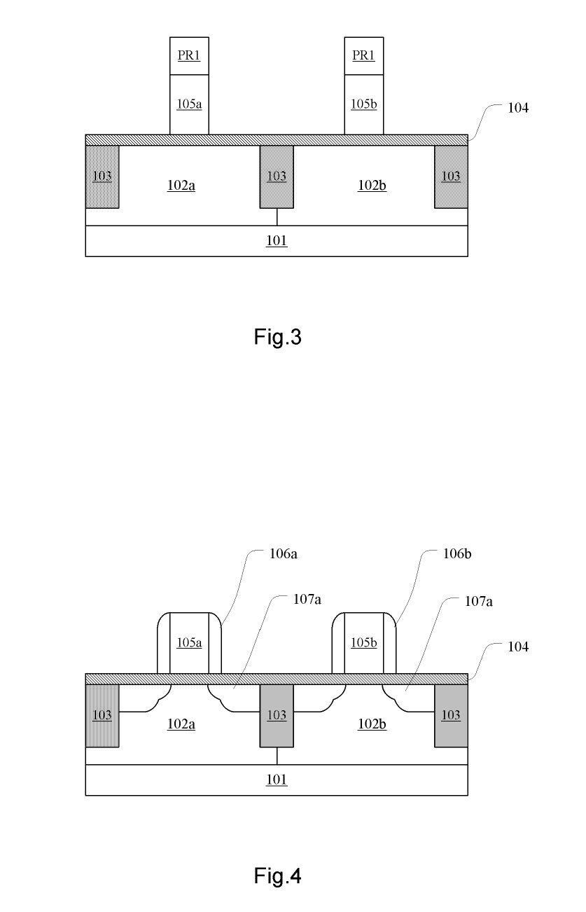

As shown in FIG. 3, exposed portions of the dummy gate conductor 105 are removed using the photoresist layer PR1 as a mask through dry etching (e.g., ion milling etching, plasma etching, reactive ion etching, or laser ablation) or wet etching using an etchant solution, to form dummy gate conductors 105a and 105g for the N type MOSFET and the P type MOSFET, respectively. In the example of FIG. 3, the dummy gate conductors 105a and 105b of the N type MOSFET and the P type MOSFET are in the strip pattern above the active regions of the N-type MOSFET and the P type MOSFET, but the dummy gate conductors 105a and 105b may be in other shapes.

Next, the photoresist layer PR1 may be removed by dissolution in a solvent or ashing. The dummy gate conductors 105a and 105b are employed as a hard mask to implement ion implantation to form extension regions of the N type MOSFET and the P type MOSFET. In a preferred example, ion implantation may be further implemented to form halo regions for the N type MOSFET and the P type MOSFET.

A nitride layer may be formed on the surface of the semiconductor structure through any of the above deposition processes. In an example, the nitride layer has a thickness of about 5-30 nm. A laterally-extending portion of the nitride layer is removed through anisotropic etching process (e.g, reactive ion etching), while vertical portions of the nitride layer on side surfaces of the dummy gate conductors 105a and 105b are left to form gate spacers 106a and 106b. As a result, the gate spacers 106a and 106b surround the dummy gate conductors 106a and 106b, respectively.

The dummy gate conductors 105a and 105b and the spacers 106a and 106b may be used as a hard mask to perform ion implantation, to form source/drain regions 107a for the N type MOSFET and source/drain regions 107b for the P type MOSFET, respectively, as shown in FIG. 4. After the source/drain ion implantation, spike annealing and/or laser annealing may be performed to activate implanted ions at a temperature of about 1000-1100° C.

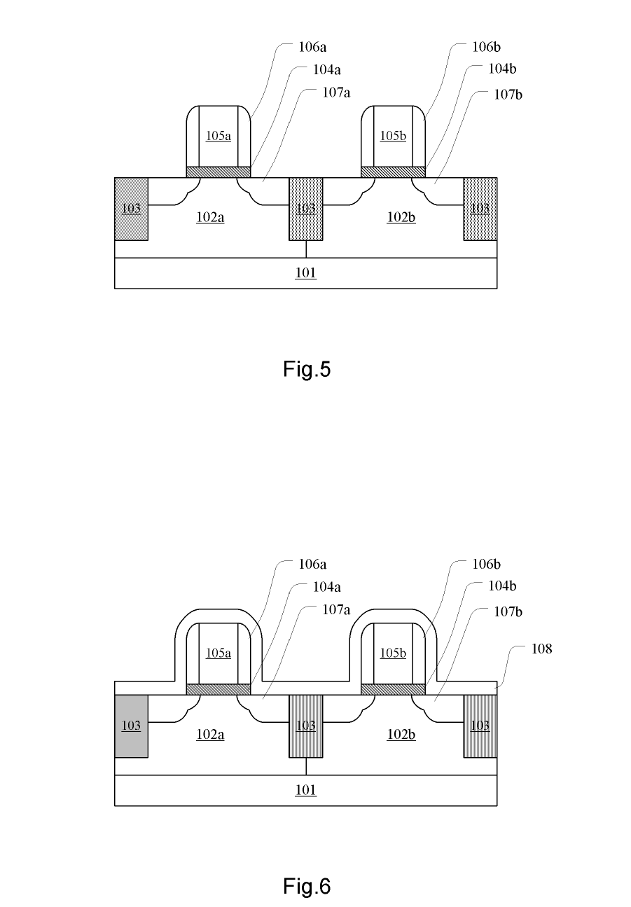

Next, by utilizing the dummy gate conductors 105a and 105b and the gate spacers 106a and 106b as a hard mask, exposed portions of the dummy gate dielectric layer 104 is selectively removed so as to expose a part of surfaces of the P well 102a of the N type MOSFET and the N well 102b of the P type MOSFET, as shown in FIG. 5. As a result, remaining portions of the dummy gate dielectric layer 104a and 104b are positioned below the dummy gate conductors 105a and 105b, respectively.

Then, a first insulating layer (e.g. silicon nitride) 108 is formed conformally on the surface of the semiconductor structure through any of the above deposition processes, as shown in FIG. 6. The first insulating layer 108 covers the dummy conductor 105a of the N type MOSFET and the P well 102a and also the dummy conductor 105b of the P type MOSFET and the N well 102b. In one example, the first insulating layer 108 is a silicon nitride layer with a thickness of about 5-30 nm.

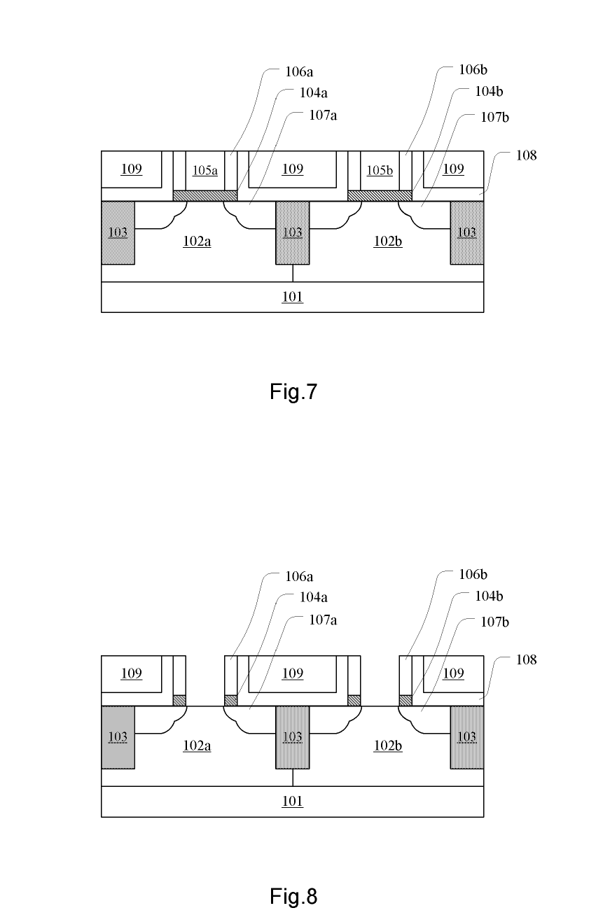

Next, a blanket second insulating layer (e.g. silicon oxide) 109 is formed on the surface of the semiconductor structure through any of the above deposition processes. The second insulating layer covers the first insulating layer 108 and fills an opening between the dummy gate conductors 105a and 105b. Chemical-mechanical polishing (CMP) is implemented to planarize the surface of the semiconductor structure. The CMP removes portions of the first insulating layer 108 and the second insulating layer 109 on top of the dummy gate conductors 105a and 105b, and may further remove portions of the dummy gate conductors 105a and 105b as well as the gate spacers 106a and 106b. As a result, the semiconductor structure with a substantially flat surface is obtained and the dummy gate conductors 105a and 105b are exposed, as shown in FIG. 7.

After that, the first insulating layer 108, the second insulating layer 109 and the gate spacers 106a and 106b are used as a hard mask to selectively remove the dummy gate conductors 105a and 105b, and further remove the portion 104a of the dummy gate dielectric layer beneath the dummy gate conductor 105a and the portion 104b of the dummy gate dielectric layer beneath the dummy gate conductor 105b through dry etching (e.g., ion milling etching, plasma etching, reactive ion etching, or laser ablation) or wet etching using an etchant solution, as shown in FIG. 8. In an example, the dummy gate conductors 105a and 105b are formed of poly-silicon, and removed through wet etching using a suitable etchant (e.g., Tetramethyl ammonium hydroxide, TMAH) solution. The etching process forms gate openings which expose top surfaces of the P well 102a of the N type MOSFET and the N well 102b of the P type MOSFET.

Next, interfacial oxide layers 110a and 110b (e.g., silicon oxide) are formed on the exposed surfaces of the P well 102a of the N type MOSFET and the N well 102b of the P type MOSFET through chemical oxidation or additional thermal oxidation. In an example, the interfacial oxide layers 110a and 110b ar formed through a rapid thermal oxidation process at a temperature of about 600-900° C. for about 20-120 s. In another example, the interfacial oxide layers 110a and 110b are formed by chemical oxidation in a solution containing ozone (O₃).

Preferably, before forming the interfacial oxide layers 110a and 110b, the surfaces of the P well 102a of the N type MOSFET and the N well 102b of the P type MOSFET are cleaned. The cleaning includes first conducting a conventional cleaning on the semiconductor structure, immersing the semiconductor structure in a mixture solution of hydrofluoric acid, isopropanol, and water, then rinsing the semiconductor structure with deionized water, and finally spin-drying the semiconductor strcture. In an example, the hydrofluoric acid, isopropanol, and water in the solution have a volume ratio of about 0.2-1.5%:0.01-0.10%:1, and the immersing is performed for about 1-10 minutes. With the cleaning process, the surfaces of the P well 102a of the N type MOSFET and the N well 102b of the P type MOSFET can be cleaned, thereby suppressing natural oxidation and particle contamination on the silicon surface, and thus facilitating formation of the interfacial oxide layers 110a and 110b with high quality.

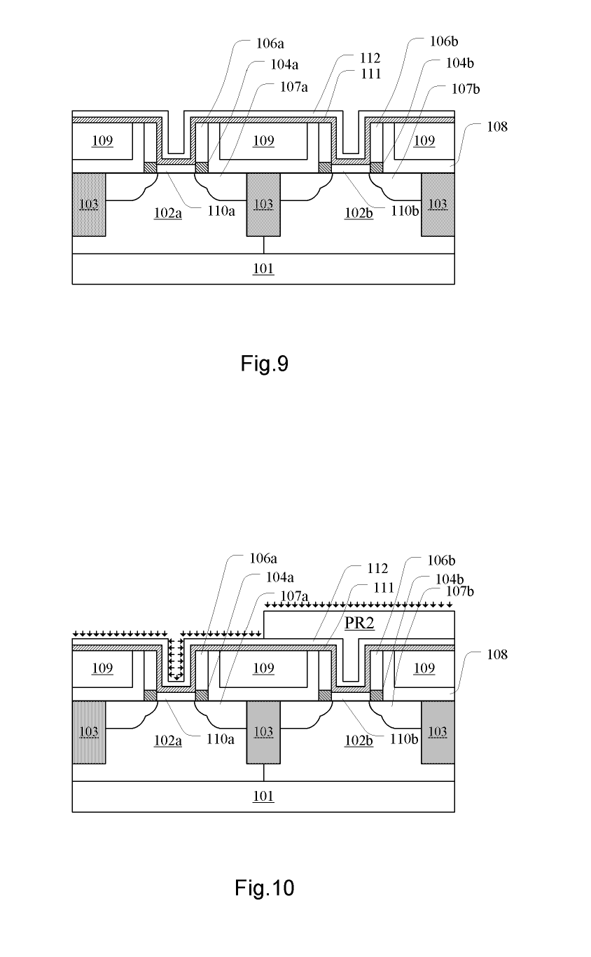

As shown in FIG. 9, a high K gate dielectric layer 111 and a first metal gate layer 112 may be formed conformally in this order on the surface of the semiconductor structure through a known deposition process, such as ALD (Atomic Layer Deposition), CVD (Chemical Vapor Deposition), MOCVD (Metal Organic Chemical Vapor Deposition), PVD (Physical Vapor Deposition), or sputtering.

The high K gate dielectric layer 111 may comprise a suitable material having a dielectric constant larger than that of SiO₂, such as any one selected from ZrO₂, ZrON, ZrSiON, HfZrO, HfZrON, HfON, HfO₂, HfAlO, HfAlON, HfSiO, HfSiON, HfLaO, HfLaON, or any of combinations thereof. The first metal gate layer 112 may comprise a suitable material that can be used to form a metal gate, such as any one selected from TiN, TaN, MoN, WN, TaC, or TaCN. In an example, the interfacial oxide layer s 110a and 110b are, for example, a layer of silicon oxide with a thickness of about 0.2-0.8 nm. The high K gate dielectric layer 110 is, for example, a layer of HfO₂ with a thickness of about 2-5 nm, and the first metal gate layer 111 is, for example, a layer of TiN with a thickness of about 1-10 nm.

Preferably, post deposition annealing of the high K gate dielectric layer may be included between forming the high K gate dielectric layer 111 and forming the first metal gate layer 112, to improve the quality of the high K gate dielectric layer. This may facilitate the subsequently-formed first metal gate layer 112 to have a uniform thickness. In an example, the post deposition annealing is rapid thermal annealing at a temperature of about 500-1000° C. for about 5-100 s.

Next, through a photolithography process including exposure and development, a patterned photoresist mask PR2 is formed to block the active region of the P type MOSFET and expose the active region of the N type MOSFET. As shown in FIG. 10, a negative dopant is implanted into the first metal gate layer 112 in the active region of the N type MOSFET through conformal doping with the photoresist mask. The negative dopant may be selected from P, As, Sb, La, Er, Dy, Gd, Sc, Yb, Er or Tb. Energy and dose for the ion implantation may be controlled so that the implanted dopant is distributed in substantially only the first metal gate layer 112, without entering the high K gate dielectric layer 111a. The energy and dose for the ion implantation may be further controlled so that the first metal gate layer 112 has suitable doping depth and concentration in order to achieve an expected threshold voltage. In an example, the energy for the ion implantation may be about 0.2 KeV-30 KeV, and the dose may be about 1E13-1E15 cm⁻². After the implantation, the photoresist mask PR2 may be removed by ashing or dissolution.

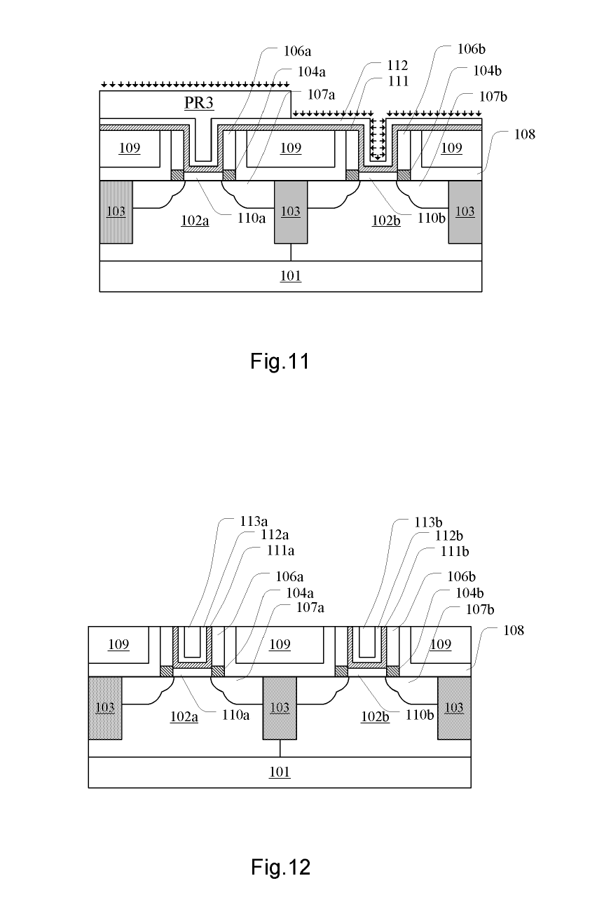

Next, through a photolithography process including exposure and development, a patterned photoresist mask PR3 is formed to block the active region of the N type MOSFET and expose the active region of the P type MOSFET. As shown in FIG. 11, a positive dopant is implanted into the first metal gate layer 112 in the active region of the P type MOSFET through conformal doping with the photoresist mask. The positive dopant may be selected from In, B, BF₂, Ru, W, Mo, Al, Ga, or Pt. Energy and dose for the ion implantation may be controlled so that the implanted dopant is distributed in substantially only the first metal gate layer 112, without entering the high K gate dielectric layer 111 b. The energy and dose for the ion implantation may be further controlled so that the first metal gate layer 112 has suitable doping depth and concentration in order to achieve an expected threshold voltage. In an example, the energy for the ion implantation may be about 0.2 KeV-30 KeV, and the dose may be about 1E13-1E15 cm⁻². After the implantation, the photoresist mask PR3 may be removed by ashing or dissolution.

A second metal gate layer 113 is formed on the surface of the semiconductor structure through any of the above known deposition processes. With the second insulating layer 109 as a stop layer, Chemical Mechanic Polishing (CMP) is performed to remove portions of the high K gate dielectric layer 111, the first metal gate layer 112, and the second metal gate layer 113 outside the gate openings, while only portions thereof inside the gate openings are left, as shown in FIG. 12. The second metal gate layer may comprise a material identical to or different from that of the first metal gate layer, such as any one selected from W, TiN, TaN, MoN, WN, TaC, or TaCN. In an example, the second metal gate layer may be a layer of W about 2-30 nm thick. As shown in the figures, a gate stack of the N type MOSFET includes the second metal gate layer 113a, the first metal gate layer 112a, the high K dielectric layer 111a, and the interfacial oxide layer 110a, and a gate stack of the P type MOSFET includes the second metal gate layer 113b, the first metal gate layer 112b, the high K dielectric layer 111b, and the interfacial oxide layer 110b. Although the gate stacks of the N and P type MOSFETs are formed by the same layers, the metal gates thereof contain dopants of opposite polarities, which enables opposite adjustments of effective work functions thereof.

The above semiconductor structure may be subjected to annealing in an atmosphere of inert gas (e.g., N₂) or weak-reducibility gas (e.g., a mixture of N₂ and H₂) after the doping of the metal gate, for example, before or after forming the second metal gate layer 113. In an example, the annealing is conducted in an oven at a temperature of about 350° C.-700° C. for about 5-30 minutes. The annealing drives the implanted dopants to diffuse and accumulate at upper and lower interfaces of the high K gate dielectric layers 111a and 111b, and further generate electric dipoles through interfacial reaction at the lower interface of the high K gate dielectric layers 111a and 111b. Here, the upper interface of the high K gate dielectric layers 111a and 111b denotes the interface with the overlying first metal gate layers 112a and 112b, and the lower interface of the high K gate dielectric layers 111a and 111b denotes the interface with the underlying interfacial oxide layers 110a and 110b.

The annealing changes the distribution of the dopants. On one hand, the dopants accumulated at the upper interface of the high K gate dielectric layers 111a and 111b can change characteristics of the metal gate, and thus facilitate adjustment of the effective function work of the respective MOSFET. On the other hand, the dopants accumulated at the lower interface of the high K gate dielectric layers 111a and 111b can generate electric dipoles of suitable polarity, and thus further facilitate adjustment of the effective function work of the respective MOSFET. As a result, the effective work function of the gate stack of the N type MOSFET can be changed in a range of about 4.1 eV to 4.5 eV, and the effective work function of the gate stack of the P type MOSFET can be changed in a range of about 4.8 eV to 5.2 eV.

The foregoing description does not illustrate every detail for manufacturing a MOSFET, such as formation of source/drain contacts, additional interlayer dielectric layers and conductive vias. Standard CMOS processes for forming these components are well known to those of ordinary skill in the art, and thus description thereof is omitted.

The foregoing description is intended to illustrate, not limit, the present disclosure. The present disclosure is not limited to the described embodiments. Variants or modifications apparent to those skilled in the art will fall within the scope of the present disclosure.

1. A method for manufacturing a semiconductor device, comprising:
forming source/drain regions in a semiconductor substrate;
forming an interfacial oxide layer on the semiconductor substrate;
forming a high K gate dielectric layer on the interfacial oxide layer;
forming a first metal gate layer on the high K gate dielectric layer;
implanting dopants to the first metal gate layer through conformal doping; and
performing annealing to change an effective work function of a gate stack comprising the first metal gate layer, the high K gate dielectric layer, and the interfacial oxide layer.

2. The method according to claim 1, wherein forming the source/drain regions comprises:
forming a dummy gate stack on the semiconductor substrate, the dummy gate stack including a dummy gate conductor and a dummy gate dielectric between the dummy gate conductor and the semiconductor substrate;
forming a gate spacer surrounding the dummy gate conductor; and
forming the source/drain regions in the semiconductor substrate with the dummy gate conductor and the gate spacer as a hard mask.

3. The method according to claim 2, further comprising between forming the source/drain regions and forming the interfacial oxide layer:
removing the dummy gate stack to form a gate opening that exposes a surface of the semiconductor substrate.

4. The method according to claim 3, further comprising between implanting the dopants to the first metal gate layer and performing annealing:
forming a second metal gate layer on the first metal gate layer to fill the gate opening; and
removing portions of the high K gate dielectric layer, and the first and second metal gate layers outside the gate opening.

5. The method according to claim 1, further comprising additional annealing between forming the high-K gate dielectric and forming the first metal gate layer, to improve quality of the high-K gate dielectric layer.

6. (canceled)

7. The method according to claim 1, wherein the first meal gate layer has a thickness of about 2-10 nm.

8. (canceled)

9. The method according to claim 1, wherein the implanting is performed at energy and dose which are controlled so that the dopants are distributed in substantially only the first metal gate layer.

10. The method according to claim 9, wherein the energy is about 0.2 KeV-30 KeV.

11. The method according to claim 9, wherein the dose is about 1E13-1E15 cm⁻².

12. The method according to claim 1, further comprising before forming the source/drain regions:
forming a well in the substrate, wherein the well has a doping type opposite to that of the source/drain regions of the semiconductor device and the subsequently formed source/drain regions are disposed in the well.

13. The method according to claim 1, wherein the semiconductor device comprises an N type MOSFET and a P type MOSFET formed on the single semiconductor substrate, and said implanting dopants to the first metal gate layer comprises:
performing ion implantation with a first dopant on the first metal gate layer of the N type MOSFET, with the P type MOSFET masked; and
performing ion implantation with a second dopant on the first metal gate layer of the P type MOSFET, with the N type MOSFET masked.

14. The method according to claim 13, wherein the first dopant comprises a dopant configured to reduce the effective work function.

15. (canceled)

16. The method according to claim 13, wherein the second dopant comprises a dopant configured to increase the effective work function.

17. (canceled)

18. The method according to claim 1, wherein the annealing is performed in an atmosphere of inert gas or weak-reducibility gas at a temperature of about 350° C.-700° C. for about 5-30 minutes.

19. A semiconductor device, comprising:
source/drain regions in a semiconductor substrate;
an interfacial oxide layer on the semiconductor substrate;
a high K gate dielectric layer on the interfacial oxide layer; and
a first metal gate layer on the high K gate dielectric layer,
wherein dopants are distributed at an upper interface between the high K gate dielectric layer and the first metal gate layer as well as at a lower interface between the high K gate dielectric layer and the interfacial oxide layer, and electrical dipoles are generated at the lower interface through interfacial reaction, to change an effective work function of a gate stack comprising the first metal gate layer, the high K gate dielectric layer, and the interfacial oxide layer.

20. The semiconductor device according to claim 19, further comprising:
a second metal gate layer on the first metal gate layer; and
a gate spacer surrounding the interfacial oxide layer, the high K gate dielectric layer, and the first and second metal gate layers.

21. The semiconductor device according to claim 19, further comprising a well in the semiconductor substrate, wherein the well has a doping type opposite to that of the source/drain regions of the semiconductor device and the source/drain regions are disposed in the well.

22. The semiconductor device according to claim 19, comprising an N type MOSFET and a P type MOSFET formed on the single semiconductor substrate, wherein a first dopant in the N type MOSFET is configured to reduce an effective work function, and a second dopant in the P type MOSFET is configured to increase an effective work function.

23. (canceled)

24. (canceled)

25. The semiconductor according to claim 19, wherein the semiconductor device comprises an N type MOSFET and the effective work function of the gate stack is in a range of 4.1 eV-4.5 eV.

26. The semiconductor according to claim 19, wherein the semiconductor device comprises a P type MOSFET and the effective work function of the gate stack is in a range of 4.8 eV-5.2 eV.
